(19) United States
(12) Patent Application Publication
(10) Pub. No.: US 2013/0001421 A1
(43) Pub. Date: Jan. 3, 2013

(54) METHOD AND APPARATUS FOR ANALYZING SAMPLE USING TERAHERTZ WAVE

(75) Inventors: Seong-Min PYO, Seoul (KR); Wang-Joo LEE, Daejeon (KR); Jae-Ick CHOI, Daejeon (KR)

(73) Assignee: Electronics and Telecommunications Research Institute, Daejeon (KR)

(21) Appl. No.: 13/534,200

(22) Filed: Jun. 27, 2012

(30) Foreign Application Priority Data
Jun. 28, 2011 (KR) 10-2011-0062922

(51) Int. Cl. G01J 5/10; H01L 27/146

(52) U.S. Cl. 250/330; 250/338.1

(57) ABSTRACT

Disclosed are a method and an apparatus for analyzing a sample using terahertz waves. The method of analyzing a sample using terahertz waves includes: generating terahertz waves; simultaneously radiating two or more electromagnetic waves with different radiation angles, using the terahertz waves with a transmitting antenna; receiving the two or more electromagnetic waves transmitting the sample with a receiving antenna; and acquiring an analysis image of the sample by processing the received two or more electromagnetic waves In accordance with the present invention, it is possible to reduce the time taken to acquire an analysis image of a sample by simultaneously radiating terahertz waves with different radiation angels from one antenna.

### CROSS-REFERENCE TO RELATED APPLICATIONS

The present application claims priority of Korean Patent Application No. 10-2011-0062922, filed on Jun. 28, 2011, which is incorporated herein by reference in its entirety.

### BACKGROUND OF THE INVENTION

1. Field of the Invention

Exemplary embodiments of the present invention relate to a method and an apparatus for analyzing a sample, and more particularly, to a method and an apparatus for analyzing a sample using terahertz waves.

2. Description of Related Art

Researches into terahertz (THz) waves have been actively conducted in recent years. Terahertz waves are electromagnetic waves in a frequency band from 0.1 THz to 100 THz and the band is also called a terahertz gap.

Since the terahertz waves have an intermediate property between electric waves and light waves, the terahertz has the advantage of making it possible to implement not only electric wave imaging, similar to the existing ultrasonic waves or microwaves, but also imaging. using optical characteristics. Further, since the wavelength is larger than that of visible light or infrared light, the performance of transmission is high and the energy is low, thus the terahertz waves are more stable than X-rays or a laser beam. Therefore, technologies using the characteristics of the terahertz waves have been variously studied in spectroscopic analysis of various substances, medical diagnosis using an imaging technique, nondestructive/noncontact type quality control, biometrics, and the like.

An image measuring system using terahertz waves has high image definition because it has wide range of spectrum information and high SNR (signal-to-noise ratio). However, since most terahertz generating apparatuses are low in output, it is necessary to scan an object after increasing the output density by concentrating energy on one point, and as a result, it takes long time to perform image measuring of a sample using terahertz waves.

FIG. 1 is a configuration diagram of an apparatus for analyzing a sample of the related art. As illustrated in FIG. 1, when a signal generating unit 100 generates terahertz waves, a horn antenna 120 radiates terahertz waves with an optional radiation angle. A lens 140 is disposed ahead of a sample such that parallel terahertz waves having a unit magnitude transmit the sample and another lens 160 is disposed behind the sample to concentrate the terahertz waves that transmit the sample. The terahertz waves concentrated through the lens is received by a horn antenna 180 and a signal processing unit 200 generates an analysis image of the sample by analyzing the received terahertz waves.

FIG. 2 is a diagram illustrating a method of scanning a sample in the related art. Referring to FIG. 2, assuming that the unit magnitude of a terahertz wave beam is 1 and the size of a sample is M×N, the number of pixels that are measured in the first row is M. The apparatus for analyzing a sample starts with the left upper pixel, 1×1, and measures the analysis image for each pixel while moving the sample to the left and right. The apparatus for analyzing a sample moves up the sample and then measures the analysis image of the pixels in the second row, after acquiring the analysis images of M pixels in the first row.

Therefore, assuming that it takes one second to acquire the analysis image of one pixel, it takes M seconds to acquire the analysis images of one row and it takes M×N seconds to acquire the analysis images of entire sample. As described above, since the time taken to acquire the analysis images of a sample is proportionate to the size of the sample when using the method of the related art, it take long time to implement a large-area two-dimensional analysis image.

Various optical delay lines have been developed to overcome the limit in measuring speed and a method using a 2D array type of photoconductive antenna detector has been developed, but there is a problem in that the spatial revolution is still low and the system structure is complicated.

### SUMMARY OF THE INVENTION

An embodiment of the present invention is directed to reduce the time taken to acquire an analysis image of a sample by simultaneously radiating terahertz waves with different radiation angles from one antenna.

Further, an embodiment of the present invention is directed to reduce the cost required for acquiring an analysis image at high speed, by providing an apparatus and a method that can radiate terahertz waves simultaneously at several radiation angles by using only a pair of transmitting and receiving devices.

The foregoing and other objects, features, aspects and advantages of the present invention will be understood and become more apparent from the following detailed description of the present invention. Also, it can be easily understood that the objects and advantages of the present invention can be realized by the units and combinations thereof recited in the claims.

A method of analyzing a sample using terahertz waves includes: generating terahertz waves; simultaneously radiating two or more electromagnetic waves with different radiation angles, using the terahertz waves with a transmitting antenna; receiving the two or more electromagnetic waves transmitting the sample with a receiving antenna; and acquiring an analysis image of the sample by processing the received two or more electromagnetic waves.

An apparatus for analyzing a sample using terahertz waves includes: a signal generating unit configured to generates terahertz waves; a transmitting antenna configured to simultaneously radiate two or more electromagnetic waves with different radiation angles, using the terahertz waves; a receiving antenna configured to receive at least two electromagnetic waves transmitting a sample; and a signal processing unit configured to acquire an analysis image of the sample by processing the received two or more electromagnetic waves.

### BRIEF DESCRIPTION OF THE DRAWINGS

FIG. 1 is a configuration diagram of an apparatus for analyzing a sample of the related art.

FIG. 2 is a diagram illustrating a method of scanning a sample in the related art.

FIG. 3 is a configuration diagram of an apparatus for analyzing a sample in accordance with an embodiment of the present invention.

FIG. 4 is a block diagram illustrating in more detail the components of a signal generating unit in accordance with an embodiment of the present invention.

FIG. 5 is a block diagram illustrating in more detail the components of a signal processing unit in accordance with an embodiment of the present invention.

FIG. 6 is a diagram illustrating a method of scanning a sample in accordance with an embodiment of the present invention.

FIG. 7 is a diagram illustrating characteristics of a leaky wave antenna in accordance with an embodiment of the present invention.

FIG. 8 is a diagram illustrating an equivalent circuit of metamaterial unit lattice of the leaky wave antenna in accordance with an embodiment of the present invention.

FIG. 9 is a diagram illustrating an equivalent circuit of transmission lines of the leaky wave antenna in accordance with an embodiment of the present invention.

FIG. 10 is a graph comparing the time taken for sample image analysis in accordance with an embodiment of the present invention with that of the related art.

FIG. 11 is a flowchart illustrating the entire flow of a method of analyzing a sample in accordance with an embodiment of the present invention.

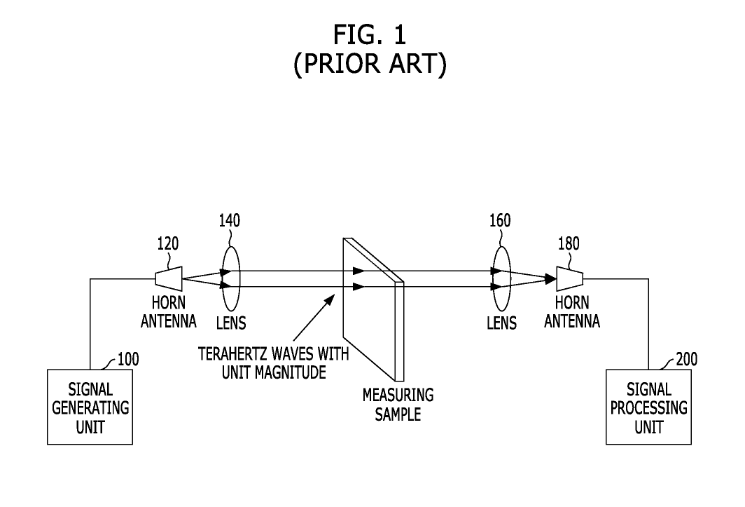

### DESCRIPTION OF SPECIFIC EMBODIMENTS

The above-mentioned objects, features, and advantages will be described in detail with reference to the accompanying drawings. Therefore, exemplary embodiments will be described in detail with reference to the accompanying drawings so that they can be easily practiced by those skilled in the art to which the present invention pertains. Further, when it is determined that the detailed description of the known art related to the present invention may obscure the gist of the present invention, the detailed description thereof will be omitted. Hereinafter, preferred embodiments of the present invention will be described in detail with reference to the accompanying drawings. In the drawings, like reference numerals denote like or similar functions in various aspects.

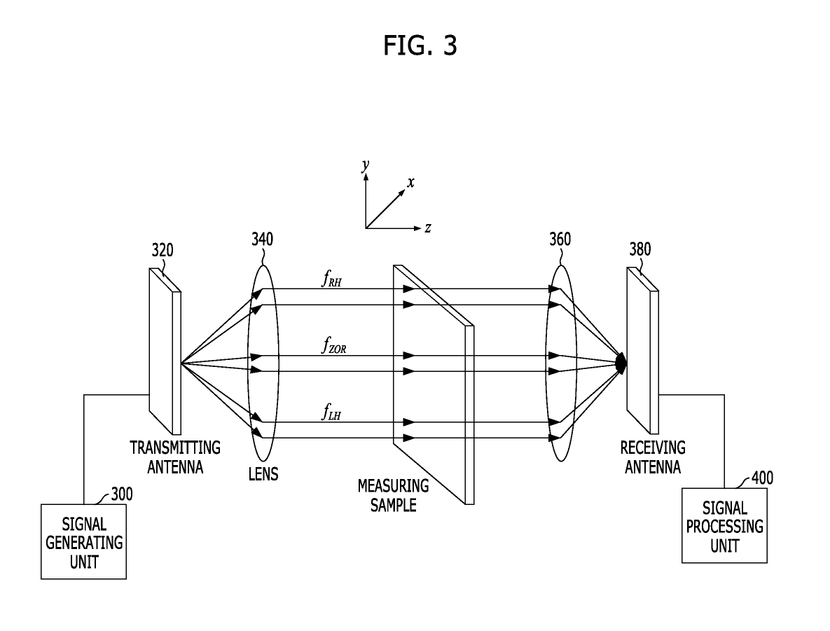

FIG. 3 is a configuration diagram of an apparatus for analyzing a sample in accordance with an embodiment of the present invention.

As illustrated in FIG. 3, an apparatus for analyzing a sample using terahertz waves include a signal generating unit 300 configured to generate terahertz waves, a transmitting antenna 320 configured to simultaneously radiate two or more electromagnetic waves with different radiation angles, using terahertz waves, a receiving antenna 380 configured to receive two or more electromagnetic waves transmitting a sample, and a signal processing unit 400 configured to acquire an analysis image of the sample by processing the received two or more electromagnetic waves, and the apparatus may further include lenses 340 and 360 disposed ahead of and behind the sample, if necessary.

First, the signal generating unit 300 generates electromagnetic waves in a terahertz band, the transmitting antenna 320 selects two or more electromagnetic waves with different frequencies from the electromagnetic waves in a terahertz band and then simultaneously radiates the selected electromagnetic waves.

In accordance with an embodiment of the present invention, it is preferable to use an antenna that makes a radiation angle different according to a frequency value; therefore, when two or more electromagnetic waves with different frequencies are simultaneously radiated, the two or more electromagnetic waves may have different radiation angles. The two or more electromagnetic waves with different radiation angles may be one of a backward wave (f_LH) in the area of an electromagnetic wave left hand rule, a zeroth-order resonant wave (f_ZOR), and a forward wave (f_RH) in the area of an electromagnetic wave right hand rule. That is, it is possible to select a frequency value when radiating electromagnetic waves from the transmitting antenna such that the electromagnetic waves are radiated to the left hand rule area, the field of the zeroth order resonant area, and the right hand rule area.

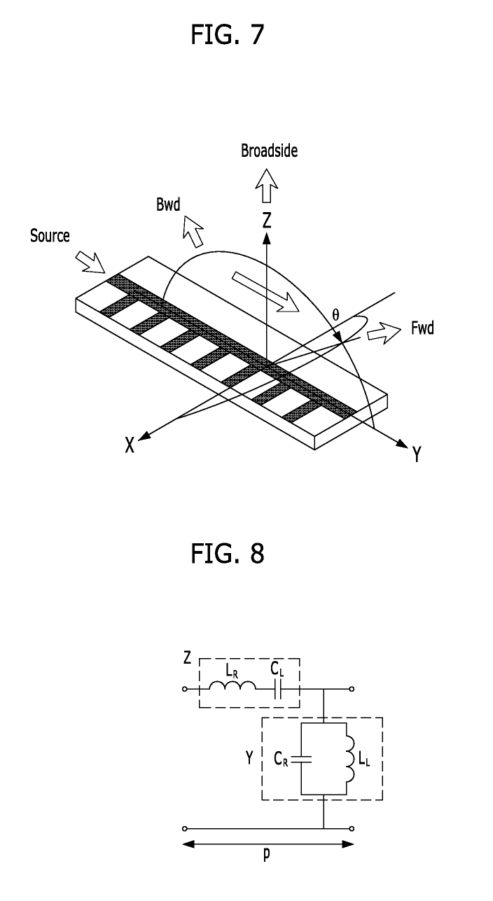

Although various kinds of antennas may be used in the present invention, a CRLH (Composite Right-Left Handed) metamaterial leaky wave antenna may be used as an example of an antenna that can cover a wide area by changing the direction according to the frequency. The radiation area of an antenna and the CRLH metamaterial leaky wave antenna will be described in detail with reference to FIGS. 7 to 9.

The transmitting antenna 320 radiates two or more electromagnetic waves with different radiation angles. Accordingly, electromagnetic waves having a unit magnitude simultaneously transmit two or more pixels and the time taken to analyzing a sample is in inverse proportion to the number of electromagnetic waves with different frequencies, for the characteristics of an apparatus for analyzing a sample using terahertz waves which measure an analysis image for each pixel by moving the sample.

The lens 340 allows two or more electromagnetic waves to travel in parallel into a sample by correcting the radiation angles of the two or more electromagnetic waves with different radiation angles that are simultaneously radiated from the transmitting antenna 320. Although the lens 340 may be an optical lens as an example herein, it is not limited thereto.

The two or more electromagnetic waves transmitting the sample are concentrated on the receiving antenna 380 through the lens 360 at the receiving end. The lens 360 at the receiving end concentrates a plurality of electromagnetic waves on an antenna by correcting the incident angle of two or more electromagnetic waves that travel in parallel into the lens 360.

Further, when the receiving antenna 380 receives the two or more electromagnetic waves transmitting the sample, the signal processing unit 400 generates an analysis image of the sample by processing the received two or more electromagnetic waves.

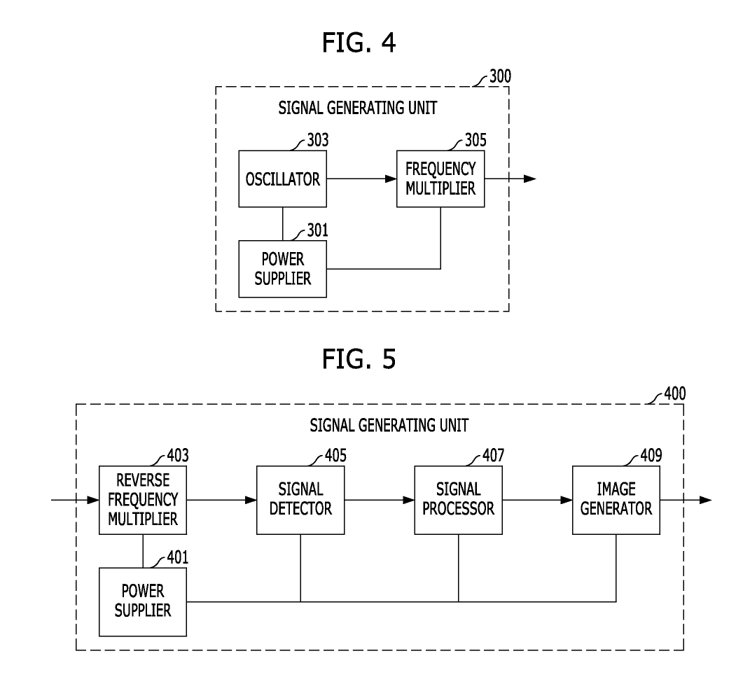

FIG. 4 is a block diagram illustrating in more detail the components of a signal generating unit in accordance with an embodiment of the present invention. Referring FIG. 4, the signal generating unit 300 includes an oscillator 303 and a frequency multiplier 305. Further, the signal generating unit 300 may further include a power supplier 301 configured to supply power to the oscillator 303 and the frequency multiplier 305.

The oscillator 303 generates initial electromagnetic waves in a predetermined frequency band. The predetermined frequency band may be a wireless frequency band including microwaves and millimeter waves. When the oscillator 303 generates initial electromagnetic waves, the electromagnetic waves with a wideband frequency generated from the oscillator 303 are input to the frequency multiplier 305.

The frequency multiplier 305 generates terahertz waves by multiplying the frequency of the input initial electromagnetic waves by an integer. Further, the generated terahertz waves are transmitted to the transmitting antenna 320, as described above. Therefore, the two or more electromagnetic waves that are radiated from the transmitting antenna 320 are electromagnetic waves with different frequencies within the terahertz band.

FIG. 5 is a block diagram illustrating in more detail the components of a signal processing unit in accordance with an embodiment of the present invention. Referring FIG. 5, the signal processing unit 400 includes a reverse frequency multiplier 403, a signal detector 405, a signal processor 407, and an image generator 409. Further, the signal processing unit 400 may further include a power supplier 401 configured to supply power to the modules included in the signal processing unit 400.

First, when two or more electromagnetic waves are received by the receiving antenna 380, the reverse frequency multiplier 403 converts the received terahertz waves into electromagnetic waves in a predetermined frequency band. The predetermined frequency band may be a wireless frequency band including microwaves and millimeter waves.

The signal detector 405 detects the magnitudes of the electromagnetic waves converted by the reverse frequency multiplier 403. A signal detecting diode such as a schottky diode may be used to detect the magnitude of the converted electromagnetic waves and the signal detector 405 detects a DC voltage having only a magnitude, except for the frequency components, using envelope detection.

The signal processor 407 determines pixel values according to the magnitudes of the electromagnetic waves detected by the signal detector 405, that is, the magnitude of the DC voltage. The signal processor 407 is implemented by a program for image control and can determine pixel values in such a way of making a high DC voltage correspond to a bright value and a low DC voltage correspond to a dark value. Therefore, in accordance with an embodiment of the present invention, since electromagnetic waves with two or more frequencies simultaneously transmit a sample, data can be processed for two or more pixels at one time.

The image generator 409 generates analysis images of the entire sample, using the pixels having the pixel value determined by the signal processor 407. Since the pixel is a unit magnitude of the electromagnetic waves transmitting the sample, it is possible to acquire the analysis images of the entire sample by reconstructing the collected pixels.

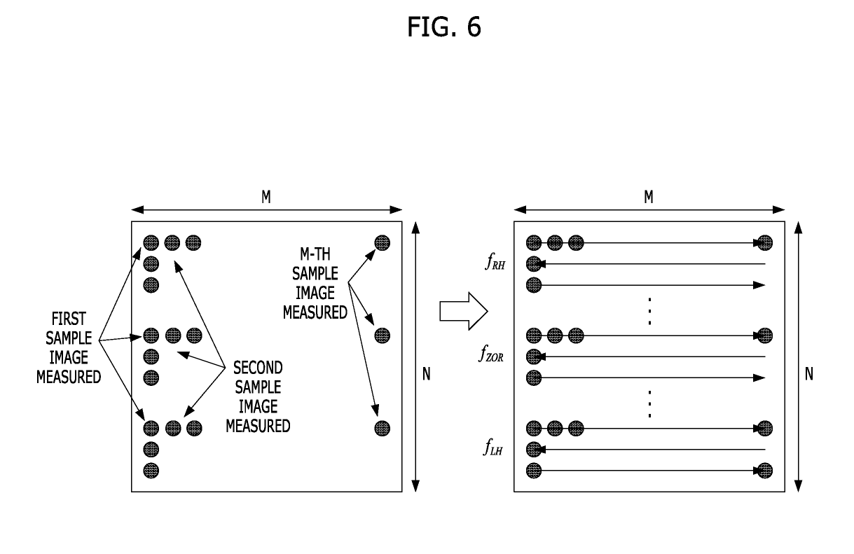

FIG. 6 is a diagram illustrating a method of scanning a sample in accordance with an embodiment of the present invention. The apparatus for analyzing a sample in the embodiment described with reference to FIG. 6 uses three electromagnetic waves with different frequencies that are radiated to a left hand rule area, a zeroth-order resonant area, and a right hand rule area.

The way that an apparatus for analyzing a sample in accordance with an embodiment of the present invention measures an analysis image for each pixel while moving the sample to the left and right is similar to that of the related art. However, unlike the way of the related art, an apparatus for analyzing a sample in accordance with an embodiment of the present invention simultaneously measures the analysis images of three pixels when measuring the analysis image of the first sample.

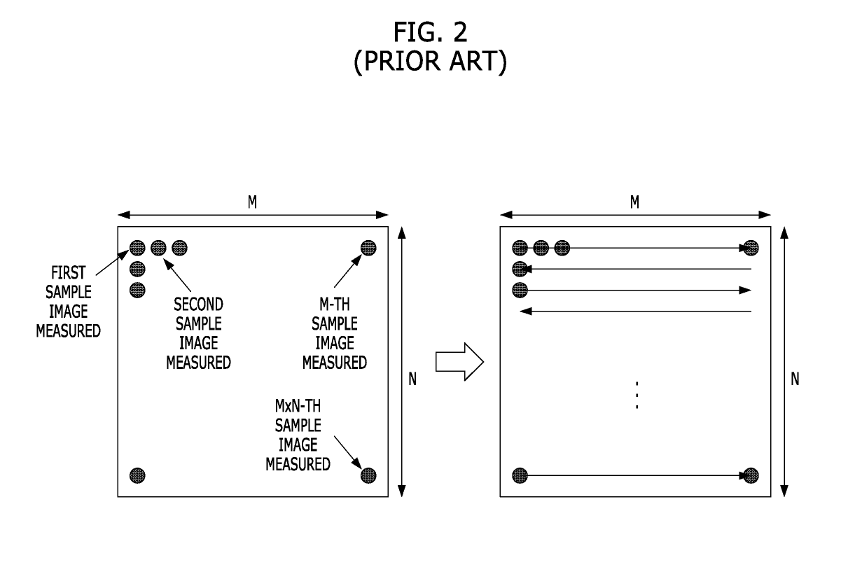

Therefore, assuming that the sample size and other conditions of FIG. 2 for describing the way of the related art are the same, an apparatus for analyzing a sample in accordance with an embodiment of the present invention acquires the analysis images for three pixels at one time; therefore, the time taken to analyze a sample is reduced by ⅓ of that of in the way of the related art. In other words, since electromagnetic waves for three areas simultaneously transmit a sample, the time taken to acquire the analysis images of one row is the same, M seconds, but the number of rows the electromagnetic waves should transmit to acquire the analysis images of the entire sample reduces to N/3, and accordingly, the time taken to acquire the analysis images of the entire sample becomes M×N/3.

As described above, although various kinds of antennas may be used in the apparatus for analyzing a sample according the present invention, in accordance with an embodiment, a CRLH metamaterial leaky wave antenna may be used. Therefore, a metamaterial leaky wave antenna will be described hereafter in detail with reference to FIGS. 7 to 9.

FIG. 7 is a diagram illustrating characteristics of a leaky wave antenna in accordance with an embodiment of the present invention.

A leaky wave antenna is a microwave antenna that is a small in beam width, changes in direction of the beam according to a frequency and covers a wide area. In accordance with an embodiment of the present invention, a CRLH (Composite Right-Left Handed) metamaterial leaky wave antenna may be used for the antenna described above.

Most materials follow the right hand rule about an electric field, a magnetic field, and a pointing vector. The materials are RH (Right Handed) materials and most of the natural materials are RH materials. The metamaterial is an artificial structure having properties of matter that is generally not found out in the nature, and unlike the RH materials, may illustrate a negative refractive index where both dielectric constant and magnetic permeability are negative, and the relative directions of vector fields follow the left hand rule. The metamaterial illustrating only a negative refractive index is called an LH metamaterial, and most metamaterials are mixtures of LH metamaterials and RH metamaterials, which are called as CRLH metamaterials.

Transmission lines made of CRLH metamaterials is suitable for a leaky wave antenna that radiates a backward wave (f_LH) in the area of an electromagnetic wave left hand rule, a zeroth-order resonanant wave (f_ZOR), and a forward wave (f_RH) in the area of an electromagnetic wave right hand rule.

Therefore, as illustrated in FIG. 7, when electromagnetic waves are input to a metamaterial leaky wave antenna source, the antenna radiates electromagnetic waves to a zeroth-order resonant area (broadside), a left hand rule area (Bwd), and a right hand rule area (Fwd). The radiation angles changes according to the frequency and the details are described below with reference to FIG. 8.

FIG. 8 is a diagram illustrating an equivalent circuit of metamaterial unit lattice of the leaky wave antenna in accordance with an embodiment of the present invention.

First, the impedance value of a metamaterial unit lattice can be expressed as follows,

$$\begin{matrix}Z = j ω {L}_{R} + \frac{1}{j ω {C}_{L}} & [ Formula 1 ] \\ Y = j ω {C}_{R} + \frac{1}{j ω {L}_{L}} & [ Formula 2 ]\end{matrix}$$

where the phase constant β and the propagation constant γ that are transmission line characteristics of the leaky wave antenna may be designed by the following formulae,

β=ω\sqrt{ZY} [Formula 3]

γ=α+jβ [Formula 4]

where a is an attenuation constant, which is the ratio per unit length that reduces when an electric wave transmits a material. When a medium is an insulator, the characteristic of non-loss without attenuation is given, and thus the attenuation constant of the transmission line of a leaky wave antenna is generally 0.

Further, the radiation angle θ when the leaky wave antenna radiates electromagnetic waves to the left hand rule area, the zeroth-order resonant area, and the right hand rule area can be designed by the following equations,

$$θ = {sin}^{- 1} ( \frac{{β}_{0} + 2 n π / p}{{k}_{0}} ) \qquad [ Formula 5 ]$$

where β₀ is a phase constant of a basic mode, n is a position high-order component, p is the length of a unit lattice of a metamaterial, and k₀ is the propagation constant in the air.

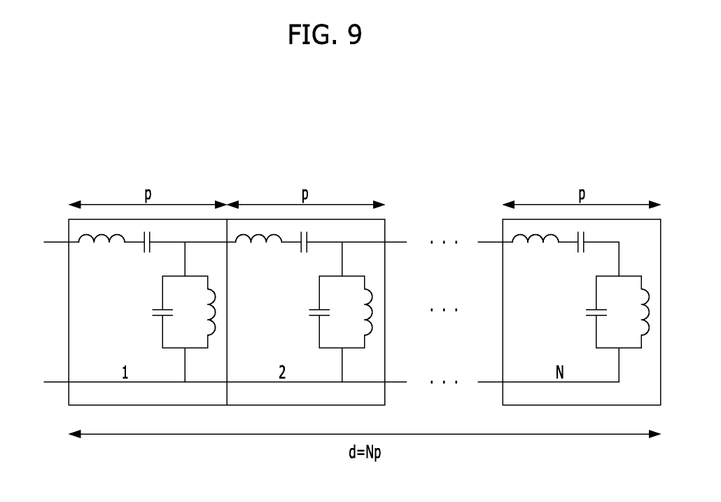

FIG. 9 is a diagram illustrating an equivalent circuit of transmission lines of the leaky wave antenna in accordance with an embodiment of the present invention. As illustrated in FIG. 9, the leaky wave antenna may be designed by connecting a plurality of metamaterial unit lattices on a dielectric substrate. The length d of all transmission lines is a value obtained by multiplying the number N of unit lattices by the length p of the unit lattice.

The resonance frequency of the metamaterial unit lattice is the frequency value of the radiated electromagnetic waves and the number k of electromagnetic waves simultaneously radiated from the antenna depends on the number N of metamaterial unit lattices. The number N of unit lattices and the number k of electromagnetic waves have the relationship of k=2N−1. Therefore, it is possible to determine the number of electromagnetic waves to radiate by adjusting the number of unit lattices and it is possible to determine the desired radiation angle by adjusting the equivalent circuit parameter value of the metamaterial unit lattice.

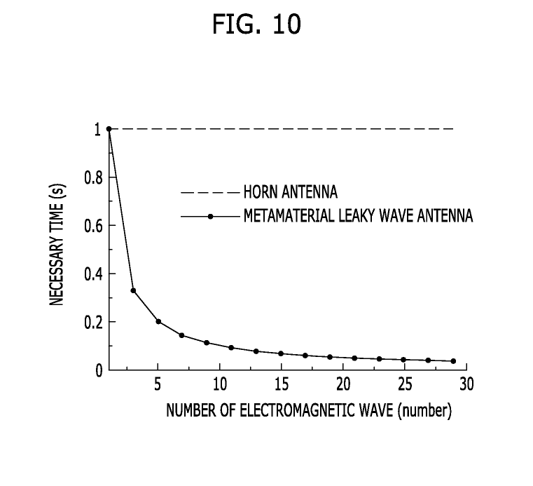

FIG. 10 is a graph comparing the time taken to acquire a sample image analysis in accordance with an embodiment of the present invention with that of the related art. An x axis is the number of electromagnetic waves radiated from an antenna and y axis is the time taken to acquire an analysis image of a sample.

The solid line illustrates when a metamaterial leaky wave antenna was used in an apparatus for analyzing a sample using terahertz waves and the dotted-line illustrates when a horn antenna of the related art was used.

As illustrated in the graph, when a metamaterial leaky wave antenna is used, the time taken to analyzing a sample reduced in proportion to the number of electromagnetic waves. Therefore, in accordance with the present invention, it is possible to considerably reduce the time taken to acquire an analysis image of a sample using terahertz waves.

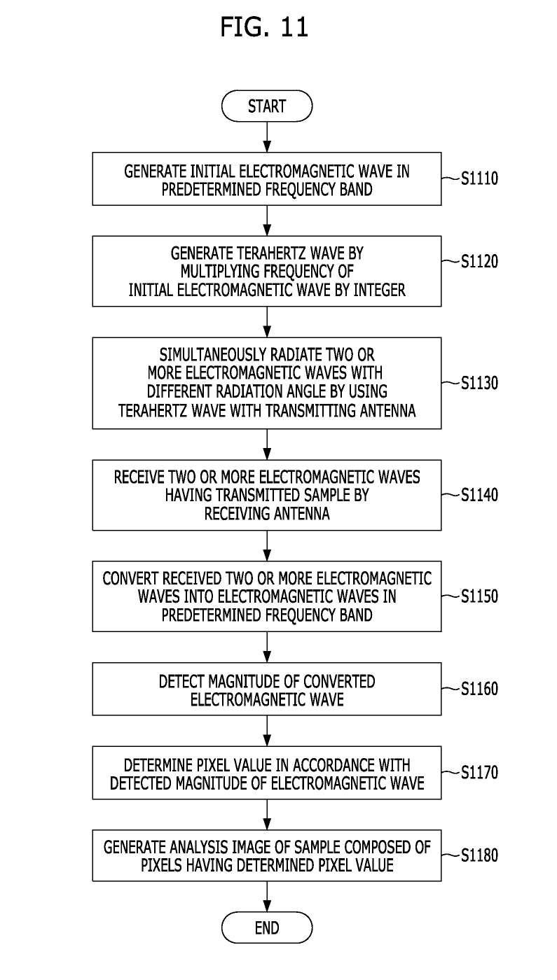

FIG. 11 is a flowchart illustrating the entire flow of a method of analyzing a sample in accordance with an embodiment of the present invention.

First, when an initial electromagnetic wave in a predetermined frequency band is generated (S1110), a terahertz wave is generated by multiplying the frequency of the initial electromagnetic wave by an integer (S1120). Next, when two or more electromagnetic waves with different radiation angels are simultaneously radiated by a transmitting antenna using terahertz waves (S1130), a receiving antenna receives the two or more electromagnetic waves transmitting a sample (S1140). In this case, the two or more electromagnetic waves with different radiation angels may be at least one of backward waves, zeroth-order resonant waves, and forward waves. Further, the transmitting antenna or the receiving antenna may be a CRLH metamaterial leaky wave. The transmitting antenna may select and radiate electromagnetic waves with two or more different frequencies, in the electromagnetic waves in the terahertz band. It is preferable that the two or more different frequencies are two or more different frequencies that are determined in advance for radiation at desired angles.

Further, though not illustrated in the drawings, the electromagnetic waves may transmit a lens configured to correct the radiation angles or the incident angles of the electromagnetic waves before or after transmitting the sample. The lens has a function of correcting the radiation angles before the two or more electromagnetic waves radiated from a transmitting antenna transmit the sample to allow the electromagnetic waves to transmit in parallel the sample. The electromagnetic waves that transmit the sample are corrected in incident angle again by a lens and concentrated on a receiving antenna.

The two or more electromagnetic waves that transmit the sample are converted into electromagnetic waves in a predetermined frequency band after being concentrated on the receiving antenna (S1150), the predetermined frequency band may be a wireless frequency band including a millimeter wave band or a microwave band.

Next, when the magnitudes of the electromagnetic waves with the frequencies converted into the wireless frequency band (S1160) is detected, only the magnitude of a DC voltage with the frequency components removed remains. A signal detecting diode such as a schottky diode may be used to detect the magnitude of the converted electromagnetic waves and it is possible to detect a DC voltage having only a magnitude, except for the frequency components, using envelope detection.

When the magnitudes of the electromagnetic waves are detected, the pixel values are determined according to the detected magnitudes of the electromagnetic waves (S1170). Further, the entire sample is analyzed by creating the analysis images of the sample composed of the pixels having the determined pixel values (s1180).

As described above, in accordance with a method and an apparatus for analyzing a sample of the present invention, it is possible to reduce the time taken to acquire an analysis image of a sample by simultaneously radiating terahertz waves with different radiation angle from one antenna and it is possible to simultaneously radiate terahertz waves at several radiation angles by using only a pair of transmitting and receiving devices; therefore, it is possible to reduce the cost required to acquire an analysis image at high speed.

In accordance with the present invention described above, it is possible to reduce the time taken to acquire an analysis image of a sample by simultaneously radiating terahertz waves with different radiation angels from one antenna.

Further, the present invention makes it possible to reduce the cost required for acquiring an analysis image at high speed, by providing an apparatus and a method that can radiate terahertz waves simultaneously at several radiation angles by using only a pair of transmitting and receiving devices.

While the present invention has been described with respect to the specific embodiments, it will be apparent to those skilled in the art that various changes and modifications may be made without departing from the spirit and scope of the invention. Accordingly, the scope of the invention is not limited to exemplary embodiments as described above and is defined by the following claims and equivalents to the scope the claims.

What is claimed is:

1. An apparatus for analyzing a sample using terahertz waves, comprising: a signal generating unit configured to generates terahertz waves;
a transmitting antenna configured to simultaneously radiate two or more electromagnetic waves with different radiation angles, using the terahertz waves;
a receiving antenna configured to receive at least two transmitting the sample; and
a signal processing unit configured to acquire an analysis image of the sample by processing the received two or more electromagnetic waves.

2. The apparatus of claim 1, wherein the two or more electromagnetic waves with different radiation angles are at least one of backward waves, zeroth-order resonant waves, and forward waves.

3. The apparatus of claim 1, wherein the transmitting antenna or the receiving antenna is a CRLH (Composite Right-Left Handed) metamaterial leaky wave antenna.

4. The apparatus of claim 1, further comprising a lens disposed ahead of or behind the sample and corrects the radiation angle or the incident angle of the two or more electromagnetic waves.

5. The apparatus of claim 1, wherein the signal generating unit includes: an oscillator configured to generate initial electromagnetic waves in a predetermined frequency band; and
a frequency multiplier configured to generates a terahertz wave by multiplying the initial electromagnetic wave by an integer.

6. The apparatus of claim 1, wherein the signal processing unit includes:
a reverse frequency multiplier configure to converting the received two or more electromagnetic waves into electromagnetic waves in a predetermined frequency band;
a signal detector configured to the magnitudes of the converted electromagnetic waves;
a signal processor configured to determine pixel values according to the magnitudes of the detected electromagnetic wave; and
an image generator configured to generate an analysis image of a sample composed of pixels having the determined pixel values.

7. A method for analyzing a sample using terahertz waves, comprising:
generating terahertz waves;
simultaneously radiating two or more electromagnetic waves with different radiation angles, using the terahertz waves with a transmitting antenna;
receiving the two or more electromagnetic waves transmitting the sample with a receiving antenna; and
acquiring an analysis image of the sample by processing the received two or more electromagnetic waves.

8. The method of claim 7, wherein the two or more electromagnetic waves with different radiation angles are at least one of backward waves, zeroth-order resonant waves, and forward waves.

9. The method of claim 7, wherein the transmitting antenna or the receiving antenna is a CRLH (Composite Right-Left Handed) metamaterial leaky wave antenna.

10. The method of claim 7, further comprising: making the two or more electromagnetic waves transmit lens configured to correct the radiation angle or the incident angel of the electromagnetic waves before or after transmitting the sample.

11. The method of claim 7, wherein the generating of terahertz waves include: generating initial electromagnetic waves in a predetermined frequency band; and generating the terahertz wave by multiplying the initial electromagnetic wave by an integer.

12. The method of claim 7, wherein the acquiring an analysis image of the sample by processing the received two or more electromagnetic waves includes:
converting the received two or more electromagnetic waves into electromagnetic waves in a predetermined frequency band;
detecting the magnitudes of the converted electromagnetic waves;
determining pixel values according to the magnitudes of the detected electromagnetic waves; and creating an analysis image of a sample composed of pixels having the determined pixel values.
